(19) United States
(12) Patent Application Publication
(10) Pub. No.: US 2026/0311747 A1
(43) Pub. Date: Oct. 8, 2026

(54) APPARATUS WITH A SELECTABLE READ CONTROL MECHANISM AND METHODS FOR OPERATING THE SAME

(71) Applicant: Micron Technology, Inc., Boise, ID (US)

(72) Inventors: William Nguyen, Dallas, TX (US); Praneeth Namala, Plano, TX (US); Seung Yeong Seo, Frisco, TX (US); Myung Ho Bae, McKinney, TX (US)

(21) Appl. No.: 19/633,922

(22) Filed: Mar. 30, 2026

Related U.S. Application Data
(60) Provisional application No. 63/784,914, filed on Apr. 7, 2025.

(51) Int. Cl. G11C 11/4091; G11C 11/4076

(52) U.S. Cl. CPC G11C 11/4091; G11C 11/4076

(57) ABSTRACT

Methods, apparatuses, and systems related to a memory device are described. The memory device includes a delay circuit configured to provide a selected delay setting from a range of delays. The delay circuit may be configured to control a relative timing between input voltages used to operate a sense amplifier for the memory device.

### CROSS-REFERENCE TO RELATED APPLICATION(S)

The present application claims priority to U.S. Provisional Patent Application No. 63/784,914, filed April 7, 2025, the disclosure of which is incorporated herein by reference in its entirety.

### TECHNICAL FIELD

The disclosed embodiments relate to devices, and, in particular, to semiconductor memory devices with a selectable amplifier control mechanism and methods for operating the same.

### BACKGROUND

An apparatus (e.g., a processor, a memory system, and/or other electronic apparatus) can include one or more semiconductor circuits configured to store and/or process information. For example, the apparatus can include a memory device, such as a volatile memory device, a non-volatile memory device, or a combination device. Memory devices, such as dynamic random-access memory (DRAM), can utilize electrical energy to store and access data.

Technological advancements are seeking and even requiring decreases in the physical sizes and/or increases in the operating speeds of the memory devices. However, decreasing the physical sizes and/or increasing the operating speeds often introduce or increase errors, failures, and other similar issues.

### BRIEF DESCRIPTION OF THE DRAWINGS

FIG. 1 is a block diagram of an apparatus in accordance with an embodiment of the present technology.

FIG. 2 is a schematic block diagram of an example read circuit in accordance with an embodiment of the present technology.

FIG. 3 is a circuit diagram of an example sense amplifier in accordance with an embodiment of the present technology.

FIG. 4 is a circuit diagram of an example sense amplifier control circuit in accordance with an embodiment of the present technology.

FIG. 5 is a flow diagram illustrating an example method of operating an apparatus in accordance with an embodiment of the present technology.

FIG. 6 is a schematic view of a system that includes an apparatus in accordance with an embodiment of the present technology.

### DETAILED DESCRIPTION

As described in greater detail below, the technology disclosed herein relates to an apparatus, such as for memory systems, systems with memory devices, related methods, etc., that controls timing delays in signals used to access stored data. For context, the apparatus can include an array of memory cells that are configured to store data by storing charges at different levels representative of bit values. In accessing the stored data, the apparatus can utilize a sense amplifier configured to amplify the stored charge levels, thereby extending the difference/separation between the charge levels and the corresponding bit values for detecting the stored data/bit values.

In some embodiments, the sense amplifier can receive and utilize multiple (e.g., two) input voltages that each transition in levels to amplify the stored charge levels. Upstream circuitry may cause the transitions of the multiple input voltages to occur at different times. The differences in the transitions may be further affected by circuit wear, temperature, operating voltage levels, and/or other environmental conditions. Moreover, manufacturing results/variations may further cause variations in the transition timing differences across multiple apparatuses.

Embodiments of the present technology includes a selectable read control mechanism configured to control the transition timings of the multiple input voltages. In some embodiments, the selectable read control mechanism can include selectable delay circuits that may be configured to control or vary a timing difference between the transitions of the multiple input voltages.

The apparatus having the selectable read control mechanism configured to delay one or more of the input voltage transitions provides decreased variation between the input voltage timing across different operating conditions and across other apparatus. Accordingly, the input voltage transitions becomes more predictable and controllable, thereby increasing the efficiency of resource usage (e.g., processing window, circuit layout, and/or the like), decreasing data sensing error rates, and/or increasing manufacturing yield for the apparatus.

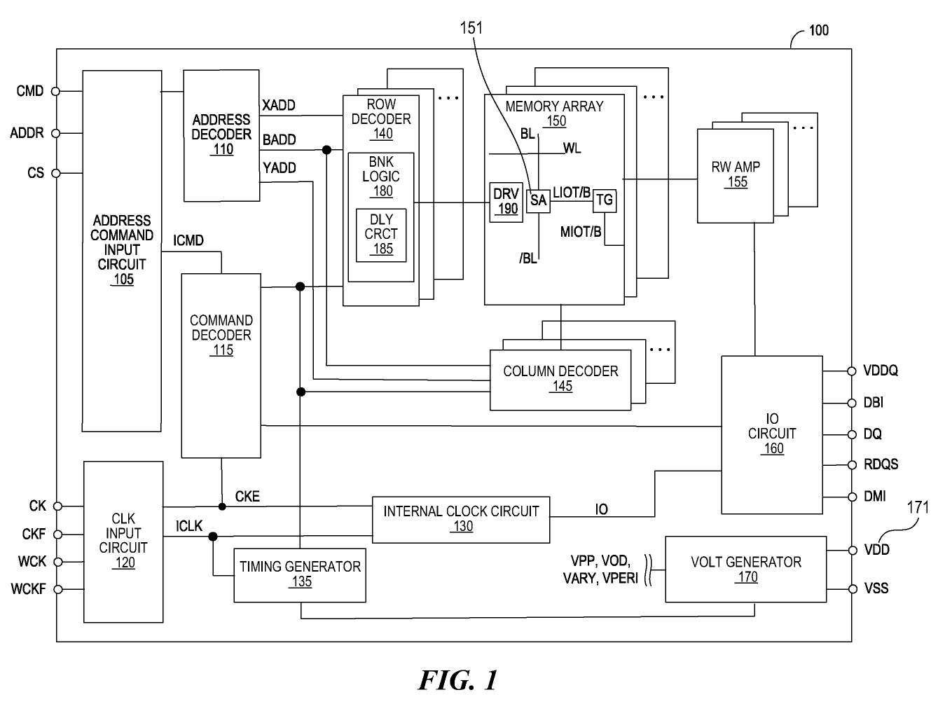

FIG. 1 is a block diagram of an apparatus 100 (e.g., a semiconductor die assembly, including a three-dimensional integration (3DI) device or a die-stacked package) in accordance with an embodiment of the present technology. For example, the apparatus 100 can include a DRAM or a portion thereof that includes one or more dies/chips.

The apparatus 100 may include an array of memory cells, such as memory array 150. The memory array 150 may include a plurality of banks (e.g., banks 0–15), and each bank may include a plurality of word-lines (WL), a plurality of bit lines (BL), and a plurality of memory cells arranged at intersections of the word-lines and the bit lines. Memory cells can include any one of a number of different memory media types, including capacitive, magnetoresistive, ferroelectric, phase change, or the like. The selection of a word-line WL may be performed by a row decoder 140, and the selection of a bit line BL may be performed by a column decoder 145.

Sense amplifiers (SAMP) 151 may be provided for corresponding bit lines BL and connected to at least one respective local I/O line pair (LIOT/B), which may in turn be coupled to at least respective one main I/O line pair (MIOT/B), via transfer gates (TG), which can function as switches. In some examples, the sense amplifiers 151 may include threshold voltage compensation circuitry that compensates for threshold voltage (Vt) differences between components of the sense amplifiers 151. The sense amplifiers 151 and transfer gates may be operated based on control signals from decoder circuitry, which may include the command decoder 115, the row decoders 140, the column decoders 145, any control circuitry of the memory array 150, or any combination thereof. The memory array 150 may also include plate lines and corresponding circuitry for managing their operation.

The apparatus 100 may employ a plurality of external terminals that include command and address terminals coupled to a command bus and an address bus to receive command signals (CMD) and address signals (ADDR), respectively. The apparatus 100 may further include a chip select terminal to receive a chip select signal (CS), clock terminals to receive clock signals CK and CKF, data clock terminals to receive data clock signals WCK and WCKF, data terminals DQ, RDQS, DBI, and DMI, power supply terminals VDD, VSS, and VDDQ.

The command terminals and address terminals may be supplied with an address signal and a bank address signal (not shown in FIG. 1) from outside. The address signal and the bank address signal supplied to the address terminals can be transferred, via a command/address input circuit 105, to an address decoder 110. The address decoder 110 can receive the address signals and supply a decoded row address signal (XADD) to the row decoder 140, and a decoded column address signal (YADD) to the column decoder 145. The address decoder 110 can also receive the bank address signal and supply the bank address signal to both the row decoder 140 and the column decoder 145.

The command and address terminals may be supplied with command signals (CMD), address signals (ADDR), and chip select signals (CS), from a memory controller and/or a nefarious chipset. The command signals may represent various memory commands from the memory controller (e.g., including access commands, which can include read commands and write commands). The chip select signal may be used to select the apparatus 100 to respond to commands and addresses provided to the command and address terminals. When an active chip select signal is provided to the apparatus 100, the commands and addresses can be decoded, and memory operations can be performed. The command signals may be provided as internal command signals ICMD to a command decoder 115 via the command/address input circuit 105. The command decoder 115 may include circuits to decode the internal command signals ICMD to generate various internal signals and commands for performing memory operations, for example, a row command signal to select a word-line and a column command signal to select a bit line. The command decoder 115 may further include one or more registers for tracking various counts or values (e.g., counts of refresh commands received by the apparatus 100 or self-refresh operations performed by the apparatus 100).

Read data can be read from memory cells in the memory array 150 designated by row address (e.g., address provided with an active command) and column address (e.g., address provided with the read). The read command may be received by the command decoder 115, which can provide internal commands to input/output circuit 160 so that read data can be output from the data terminals DQ, RDQS, DBI, and DMI via read/write amplifiers 155 and the input/output circuit 160 according to the RDQS clock signals. The read data may be provided at a time defined by read latency information RL that can be programmed in the apparatus 100, for example, in a mode register (not shown in FIG. 1). The read latency information RL can be defined in terms of clock cycles of the CK clock signal. For example, the read latency information RL can be a number of clock cycles of the CK signal after the read command is received by the apparatus 100 when the associated read data is provided.

Write data can be supplied to the data terminals DQ, DBI, and DMI according to the WCK and WCKF clock signals. The write command may be received by the command decoder 115, which can provide internal commands to the input/output circuit 160 so that the write data can be received by data receivers in the input/output circuit 160 and supplied via the input/output circuit 160 and the read/write amplifiers 155 to the memory array 150. The write data may be written in the memory cell designated by the row address and the column address. The write data may be provided to the data terminals at a time that is defined by write latency WL information. The write latency WL information can be programmed in the apparatus 100, for example, in the mode register. The write latency WL information can be defined in terms of clock cycles of the CK clock signal. For example, the write latency information WL can be a number of clock cycles of the CK signal after the write command is received by the apparatus 100 when the associated write data is received.

The power supply terminals may be supplied with power supply potentials V_{DD} and V_{SS}. These power supply potentials V_{DD} and V_{SS} can be supplied to an internal voltage generator circuit 170. In some embodiments, the power supply potentials can include a system voltage 171 (V_{DD}). The internal voltage generator circuit 170 can generate various internal potentials V_{PP}, V_{OD}, V_{ARY}, V_{PERI}, and the like based on the power supply potentials V_{DD} and V_{SS}. The internal potential V_{PP} can be used in the row decoder 140, the internal potentials V_{OD} and V_{ARY} can be used in the sense amplifiers included in the memory array 150, and the internal potential V_{PERI} can be used in many other circuit blocks.

The power supply terminal may also be supplied with power supply potential V_{DDQ}. The power supply potential V_{DDQ} can be supplied to the input/output circuit 160 together with the power supply potential VSS. The power supply potential V_{DDQ} can be the same potential as the power supply potential V_{SS} in an embodiment of the present technology. The power supply potential V_{DDQ} can be a different potential from the power supply potential V_{DD} in another embodiment of the present technology. However, the dedicated power supply potential V_{DDQ} can be used for the input/output circuit 160 so that power supply noise generated by the input/output circuit 160 does not propagate to the other circuit blocks.

The clock terminals and data clock terminals may be supplied with external clock signals and complementary external clock signals. The external clock signals CK, CKF, WCK, WCKF can be supplied to a clock input circuit 120. The CK and CKF signals can be complementary, and the WCK and WCKF signals can also be complementary. Complementary clock signals can have opposite clock levels and transition between the opposite clock levels at the same time. For example, when a clock signal is at a low clock level a complementary clock signal is at a high level, and when the clock signal is at a high clock level the complementary clock signal is at a low clock level. Moreover, when the clock signal transitions from the low clock level to the high clock level the complementary clock signal transitions from the high clock level to the low clock level, and when the clock signal transitions from the high clock level to the low clock level the complementary clock signal transitions from the low clock level to the high clock level.

Input buffers included in the clock input circuit 120 can receive the external clock signals. For example, when enabled by a clock/enable signal from the command decoder 115, an input buffer can receive the clock/enable signals. The clock input circuit 120 can receive the external clock signals to generate internal clock signals ICLK. The internal clock signals ICLK can be supplied to an internal clock circuit 130. The internal clock circuit 130 can provide various phase and frequency controlled internal clock signals based on the received internal clock signals ICLK and a clock enable (not shown in FIG. 1) from the command/address input circuit 105. For example, the internal clock circuit 130 can include a clock path (not shown in FIG. 1) that receives the internal clock signal ICLK and provides various clock signals to the command decoder 115. The internal clock circuit 130 can further provide input/output (IO) clock signals. The IO clock signals can be supplied to the input/output circuit 160 and can be used as timing signals for determining output timing of read data and/or input timing of write data. The IO clock signals can be provided at multiple clock frequencies so that data can be output from and input to the apparatus 100 at different data rates. A higher clock frequency may be desirable when high memory speed is desired. A lower clock frequency may be desirable when lower power consumption is desired. The internal clock signals ICLK can also be supplied to a timing generator 135 and thus various internal clock signals can be generated.

The apparatus 100 can be connected to any one of a number of electronic devices capable of utilizing memory for the temporary or persistent storage of information, or a component thereof. For example, a host device of apparatus 100 may be a computing device such as a desktop or portable computer, a server, a hand-held device (e.g., a mobile phone, a tablet, a digital reader, a digital media player), or some component thereof (e.g., a central processing unit, a co-processor, a dedicated memory controller, etc.). The host device may be a networking device (e.g., a switch, a router, etc.) or a recorder of digital images, audio and/or video, a vehicle, an appliance, a toy, or any one of a number of other products. In one embodiment, the host device may be connected directly to apparatus 100; although in other embodiments, the host device may be indirectly connected to memory device (e.g., over a networked connection or through intermediary devices).

In storing data, the apparatus 100 can be configured to store targeted levels of charges in the memory cells of the memory array 150. The stored data can be accessed (e.g., read) by effectively determining the level of charges stored at the targeted location (e.g., read address). The charge level determination can utilize the sense amplifier 151 described above.

However, as circuit components become smaller, clock speeds can be increased and the voltage/power consumption requirements can be reduced. Such changes can reduce the duration and/or margins (e.g., sense margin) of the sense amplifier 151. Further, small variances in the performance between circuit components of the sense amplifiers 151 (e.g., due to process, voltage, and temperature (PVT) variance) may reduce operational reliability of the apparatus 100. For example, the system voltage 171 (V_{DD}) can vary according to an external power supply and/or external operating environment, and the variation in the system voltage 171 can negatively affect the sense margin.

To offset, reduce, or remove the negative effects on the sense margin, the apparatus can include a bank logic 180 having a delay circuit 185. The bank logic 180 can include circuitry configured to control operations of the sense amplifier 151. Effectively, the bank logic 180 can control signals that correspond to various phases and actions for the sense amplifier 151 in amplifying the stored charge levels. The delay circuit 185 can be configured to control relative timing of one or more such operational signals, such as internal voltages used by the sense amplifier 151 in amplifying the stored charges. The output of the delay circuit 185 can be provided to a driver 190 that provides the corresponding power for the operational signals for the sense amplifier. Details regarding the sense amplifier 151, the bank logic 180, and the delay circuit 185 are further described below.

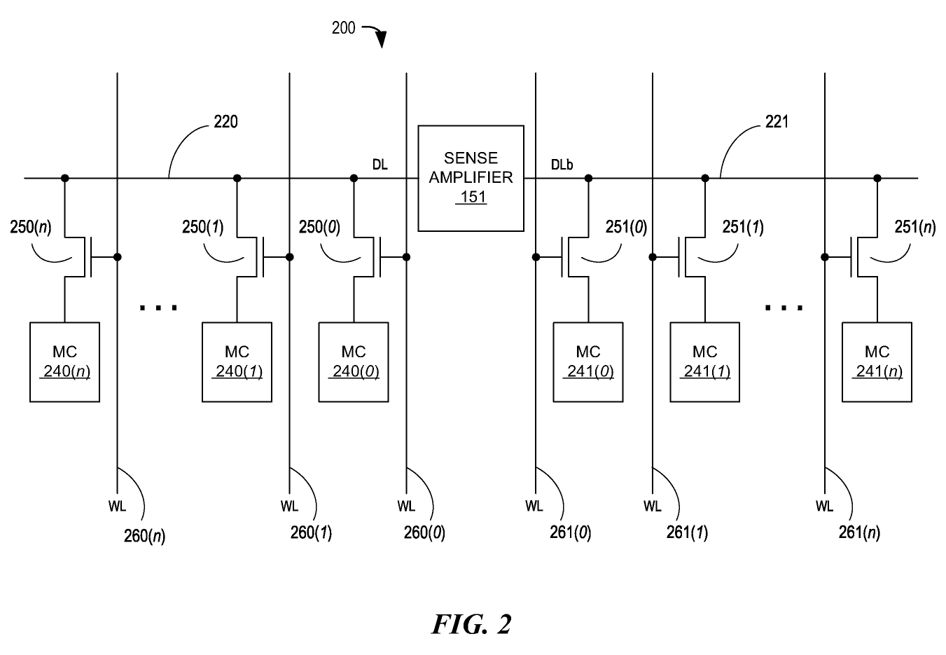

FIG. 2 is an example schematic block diagram of an example read circuit 200 in accordance with an embodiment of the present technology. In some embodiments, the apparatus 100 can include the read circuit 200 with the sense amplifier 151 coupled to a pair of complementary digit/bit lines DL 220 and DLb 221.

Memory cells 240(0)-(n) may be selectively coupled through respective access devices (e.g., transistors) 250(0)-(n) to the DL 220, and memory cells 241(0)-(n) may be selectively coupled through respective access devices (e.g., transistors) 251(0)-(n) to the DLb 221. One or more sets of word-lines WL 260(0)-(n) can be configured to control the access devices 250(0)-(n), thereby selectively connecting the memory cells 240(0)-(n) to the DL 220 through the corresponding access devices 250(0)-(n). For example, the word-lines WL 260(0)-(n) can be coupled to gates of corresponding transistors and provide control signals for operating the corresponding transistors. Similarly, word-lines WL 261(0)-(n) can control the corresponding access devices 251(0)-(n) to selectively connect the memory cells 241(0)-(n) to the DLb 221. The sense amplifier 151 may be controlled via control signals received through a decoder circuit and/or the bank logic 180 of FIG. 1, such as the command decoder 115 of FIG. 1, the row decoder 140 of FIG. 1, the column decoder 145 of FIG. 1, and/or control circuitry of the memory cell array 150.

In some embodiments, the memory can operate according to phases or modes. For example, the memory can operate according to a first phase (e.g., precharge phase) that is initiated in response to a precharge command PRE. During the precharge phase, the word-lines WL 260(0)-(n) and 261(0)-(n) may be set to an inactive state, and in response, the access devices 250(0)-(n) and 251(0)-(n) may be disabled. Further, the digit lines DL 220 and DLb 221 may be precharged to and held at a precharge voltage, such as a digit line precharge voltage V_{BLP}, until transitioning to a second phase. The sense amplifier 151 can include internal nodes that are configured to provide a sensed data state to an output (e.g., gut nodes). During the precharge phase, the internal nodes can also be held at the precharge voltage (e.g., at V_{BLP}) until transitioning to the second phase.

In some embodiments, the sense amplifier 151 can include a threshold voltage compensation circuitry configured to compensate for threshold voltage (Vt) mismatches between components of the sense amplifier 151 during a threshold voltage compensation phase. To perform the threshold voltage compensation, the sense amplifier 151 may, during a threshold voltage compensation phase, precharge or bias the digit lines DL 220 and DLb 221 using internal nodes such that a voltage difference between the digit line DL 220 and the DLb 221 is approximately equal to threshold voltage differences between at least two circuit components of the sense amplifier 151. In some examples, the threshold voltage difference may be based on threshold voltages of transistors of the sense amplifier 151. Compensating for Vt differences between circuit components within the sense amplifier 151 can improve reliability of the apparatus 100.

The memory can operate according to a third phase (e.g., a sense amplifier activation phase) following the second phase. During the activation phase, one or more of the word-lines WL 260(0)-(n) and 261(0)-(n) may be set to an active state. In response, one or more of the access devices 250(0)-(n) and 251(0)-(n) may be enabled to couple a respective memory cell of the memory cells 240(0)-(n) and 241(0)-(n) to one of the digit lines DL 220 and DLb 221. The sense amplifier 151 may be configured to perform a sense operation to sense a data state of the coupled memory cell. That is, during a sense operation, a data state stored by the coupled memory cell is sensed and amplified by the sense amplifier 151 to drive one of the digit line DL 220 or the digit line DLb 221 to a high or low voltage level corresponding to the sensed data state. The sense amplifier 151 can drive the other digit line of the digit lines DL 220 and DLb 221 to the complementary voltage level during the sense operation.

After the sense operation, the circuitry of the memory may remain in the activation phase or may transition back to the precharge phase in response to a precharge command PRE. Similarly, one of the memory cells 241(0)-(n) can be coupled to the digit line DLb 221 through the respective access device 251(0)-(n) in response to a respective word-line 261(0)-(n) becoming active. A data state stored by the memory cell can be sensed and amplified by the sense amplifier 151 to drive the digit line DLb 221 to a high or low voltage level corresponding to the sensed data state. The other digit line DL 220 can be driven to the complementary voltage level (e.g., the high voltage level is complementary to the low voltage level and the low voltage level is complementary to the high voltage level) during the sense operation.

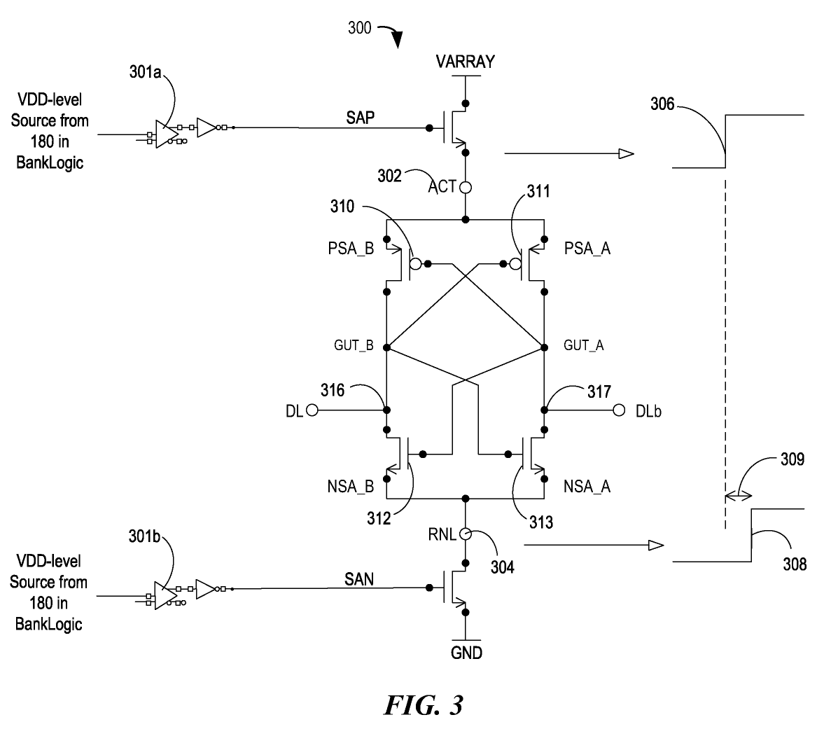

FIG. 3 is a schematic diagram of an example sense amplifier 300 (“sense amplifier 300”) in accordance with an embodiment of the present technology. The sense amplifier 300 can correspond to the sense amplifiers 151 of FIG. 1.

In some embodiments, the sense amplifier 300 can include a first set of transistors (e.g., p-type field effect transistors (PFETs)) 310 and 311, each having a terminal (e.g., drains) coupled to nodes 316 and 317, respectively. Second terminals (e.g., respective gates) of the transistors 310 and 311 can be coupled to the nodes 317 and 316, respectively. Third terminals (e.g., sources) of the transistors 310 and 311 can be coupled to a first rail voltage 302 (ACT).

The sense amplifier 300 can further include n-type field-effect transistors (NFETS) 312 and 313 that are opposite the PFETS 310 and 311 across the nodes 316 and 317. For example, the third terminals (e.g., sources) of the transistors 312 and 313 can be coupled to a second rail voltage 304 (RNL), and the first terminals (e.g., the drains) of transistors 312 and 313 can be coupled to the nodes 316 and 317, respectively. Given the connections and the function of the nodes 316 and 317, these nodes may be called “gut nodes” in a non-limiting manner. Further, a digit line DL (e.g., the digit line DL 220 of FIG. 2) can be coupled to the node 316 and a digit line DLb (e.g., the digit line DLb 221 of FIG. 2) can be coupled to the node 317.

In operating the sense amplifier 300, the bank logic 180 of FIG. 1 can control inputs thereto, such as the first rail voltage 302 and the second rail voltage 304, using a first control voltage (SAP) and a second control voltage (SAN), respectively. The first and second rail voltages 302 and 304 of the sense amplifier 300 can respectively be switched on by the first control signal SAP and the second control signal SAN. The first control signal SAP can be generated by a SAP level shifter 301a, and the and the second control signal SAN can be generated by a SAN level shifter 301b. The SAP level shifter 301a and the SAN level shifter 301b can use VDD level voltage sources from the bank logic 180 of FIG. 1 to generate the respective control signals. Thus, the SAP and SAN level shifters can be sensitive to VDD voltage levels, and as the VDD level changes, the delay of each level shifter can change and cause a delay 309 that varies across VDD range. In amplifying the stored charges, the first control signal (e.g., between 1.5V and 1.9V) can be higher than the second control signal (e.g., between 0.9V and 1.3V) The bank logic 180 can transition the first control signal and the second control signal , such as for a first voltage transition 306 for the first rail voltage 302 and a second voltage transition 308 for the second rail voltage 304. The first voltage transition 306 and the second voltage transition 308 can be temporally correlated. For example, for certain operations or phases of the sense amplifier 300, the first voltage transition 306 and the second voltage transition 308 can be targeted to occur simultaneously or after a targeted duration.

Given the different signal paths, the first voltage transition 306 and the second voltage transition 308 can have the unintended delay 309 between the transitions. The unintended delay 309 can correspond to a duration extending beyond a threshold range associated with the relative timing. As an illustrative example, the first voltage transition 306 and the second voltage transition 308 can be targeted to be concurrent, and the unintended delay 309 can be the duration that lapses between the first voltage transition 306 and the second voltage transition 308. In some embodiments, the unintended delay 309 can vary according to different environmental conditions, such as operating temperature, manufacturing differences in the circuits, different levels of the system voltage 171 of FIG. 1, and/or the like.

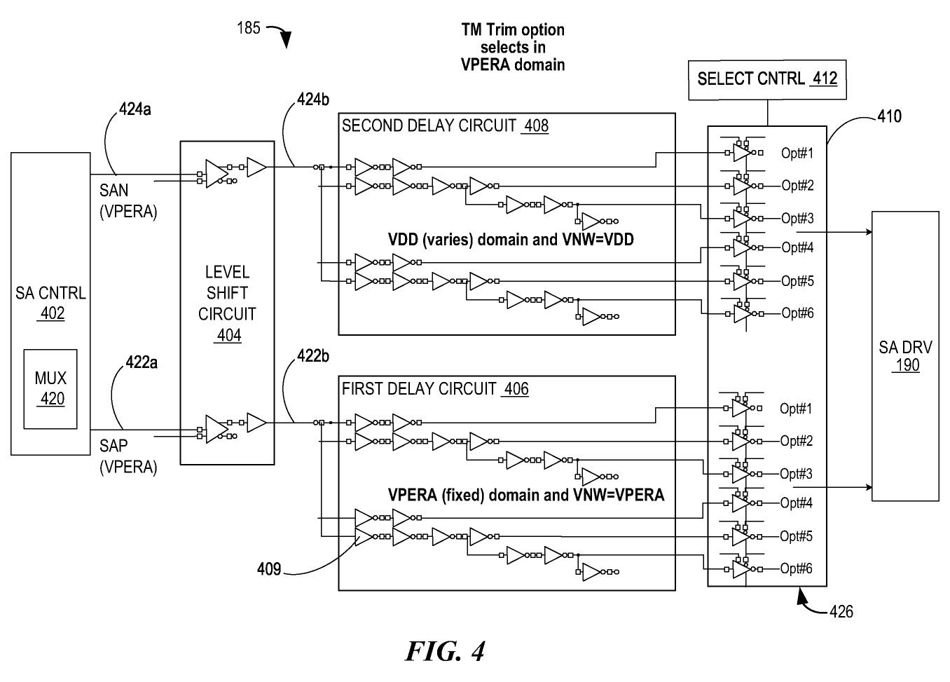

FIG. 4 is a circuit diagram of an example sense amplifier control circuit in accordance with an embodiment of the present technology. In some embodiments, the sense amplifier control circuit can include the delay circuit 185 within the bank logic 180 of FIG. 1. For example, the sense amplifier control circuit can include an amplifier control circuit 402 (e.g., a portion of the bank logic 180) configured to control the timings of sense amplifier control signals, such as the first rail voltage 302 of FIG. 3 and/or the second rail voltage 304 of FIG. 3. In other words, the amplifier control circuit 402 can control the first voltage transition 306 of FIG. 3 and the second voltage transition 308 of FIG. 3. The amplifier control circuit 402 can control or transition (1) a first control voltage 422 (SAP) corresponding to the first rail voltage 302 and/or (2) a second control voltage 424 (SAN) corresponding to the second rail voltage 304.

The first control voltage 422 and the second control voltage 424 can be provided to a level shift circuit 404 that provides a targeted voltage for and/or in response to the first control voltage 422 and the second control voltage 424. In some embodiments, the level shift circuit 404 can be configured to adjust one or both of the first control voltage 422 and the second control voltage 424. The first control voltage 422 and the second control voltage 424 can include input voltages at VPERA (voltage 422a and 424a, respectively) that are level-shifted to VDD levels (adjusted output levels 422b and 424b, respectively). For example, the first adjusted control voltage 422b can correspond to the VPERA domain (e.g., a fixed level within a range between 1.0V and 1.1V) and the second adjusted control voltage 424b can correspond to the system voltage 171 of FIG. 1 (e.g., a variable level within a threshold range, such as between 1.0V and 1.3V) where VDD is greater than or equal to VPERA.

The sense amplifier control circuit can include a selectable delay circuit for the first adjusted control voltage 422b and/or the second adjusted control voltage 424b. For the illustrated example, the delay circuit 185 can include (1) a first delay circuit 406 for the first adjusted control voltage 422b and (2) a second delay circuit 408 for the second adjusted control voltage 424b. Each of the first delay circuit 406 and the second delay circuit 408 can include multiple parallel paths that have different numbers of delay components 409 (e.g., inverters, flipflops, etc.). Accordingly, the parallel delay paths can delay the input signal (e.g., corresponding one of the first adjusted control voltage 422b and the second adjusted control voltage 424b) by different durations. As shown in FIG. 4, a first delay path (e.g., option 1) can have two delay agents in series, a second delay path (e.g., option 2) can have four delay agents in series, a third path (option 3) can have five, and so forth. In some embodiments, the first delay circuit 406 and the second delay circuit 408 can have matching delay paths.

The delayed outputs can be provided to a selector circuit 410 configured to select and pass one of the delayed signals. Accordingly, the delay circuit 185 can use the first delay circuit 406 and/or the second delay circuit 408 to control the timings of the first adjusted control voltage 422b and the second adjusted control voltage 424b.

In some embodiments, the sense amplifier control circuitry can be tested (e.g., during device qualification, manufacturing, system integration, and/or the like before deployment) under a variety of operating conditions. For example, the apparatus 100 of FIG. 1 can be tested by observing the delays in the input voltages (e.g., at the output of each of the delay paths) across different levels of the system voltage 171. The apparatus 100 can have a predetermined setting, such as a fuse setting and/or a trim setting, that represents one or a combination of the paths (e.g., corresponding options) providing the most consistent or the smallest variations to cancel out the unintended delay 309 of FIG. 3 or the variations thereof across the different levels of the system voltage 171. The predetermined setting can be stored in and/or provided to a selection control circuit 412 that is configured to select a corresponding one or combination of the output paths within the first delay circuit 406 and/or the second delay circuit 408.

The corresponding delayed versions of the first adjusted control voltage 422b and the second adjusted control voltage 424b can be provided to the driver 190. The driver 190 can generate the source from the bank logic 180 of FIG. 1 and drive the corresponding transitions (e.g., the first voltage transition 306 of FIG. 3 and/or the second voltage transition 308 of FIG. 3) according to the delayed versions of the first adjusted control voltage 422b and the second adjusted control voltage 424b, and the corresponding delay can help to mitigate the variation of the delay 309 across the operating VDD range. The sense amplifier 151 can receive and operate according to the generated input voltages as described above.

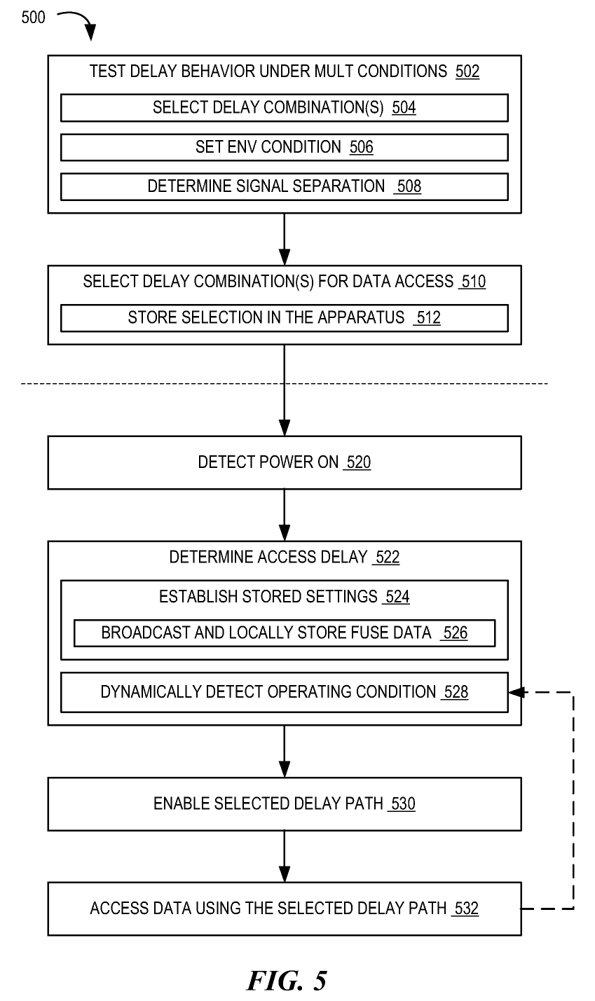

FIG. 5 is a flow diagram illustrating an example method 500 of operating an apparatus (e.g., the apparatus 100 of FIG. 1) in accordance with an embodiment of the present technology. For example, the method 500 can be for operating the read circuit 200 of FIG. 2, the sense amplifier 151 of FIG. 1, the bank logic 180 of FIG. 1, the delay circuit 185 of FIGS. 1 and 4, and/or other circuits described above. The method 500 can be for controlling a delay or a separation between control signals used to operate the sense amplifier 151.

At block 502, the method 500 can include testing the delay behavior of the apparatus 100 under multiple conditions.

In testing under the multiple conditions, the method 500 can include testing multiple delay combinations, such as multiple combinations of the delay paths within the first delay circuit 406 of FIG. 4 and/or the second delay circuit 408 of FIG. 4. In some embodiments, the apparatus 100 can include and/or set the delay circuit for one of the signals, such as the first delay circuit 406 for controlling the timing of the first input voltage 302 of FIG. 3. In other embodiments, the apparatus 100 can include the delay circuit for all signals, such as to provide different granularities and/or to provide balance in the circuits across the control signals.

In some embodiments, the apparatus 100 can simultaneously test a limited number of delay paths. For such embodiments, the method 500 can include selecting one or more delay combinations as shown in block 504. For example, the apparatus 100 can follow a predetermined sequence and enable a selected number of delay paths within the first delay circuit 406 and/or the second delay circuit 408. The apparatus 100 can be configured to test different combinations of the delay paths across multiple iterations or sessions.

Alternatively, in other embodiments, the apparatus 100 can simultaneously test the delay paths within the first delay circuit 406 and/or the second delay circuit 408. For such embodiments, the apparatus 100 can simultaneously communicate a test signal across the delay paths.

At block 506, the apparatus 100 can be subject to a targeted environmental condition. For example, the system voltage 171 of FIG. 1 provided to the apparatus 100 can be adjusted to a targeted level. The apparatus 100 can be connected to a testing system that varies the VDD, such as for a number of different levels between 0.9V – 1.5V. Additionally or alternatively, the apparatus 100 can be subjected to different environmental temperatures.

At block 508, the method 500 can include determining the signal separation(s) (e.g., the unintended delay 309 of FIG. 3 for each of the enabled delay paths) under the tested environmental condition. The apparatus 100 can determine the signal separations by generating the first adjusted control voltage 422b of FIG. 4 and the second adjusted control voltage 424b of FIG. 4 and measuring the outputs of the delay circuits. The signal separations can be computed as a difference between one of the delay paths for the first adjusted control voltage 422b and the second adjusted control voltage 424b or a corresponding delay path.

As mentioned above, the method 500 can include testing the available delay paths of the first delay circuit 406 and/or the second delay circuit 408 under multiple environmental conditions. In some embodiments, the method 500 can implement the processing steps illustrated by blocks 504- 508 using an iterative process.

Using the collected data (e.g., the signal separations under different environmental conditions), the method 500 can include selecting one or more delay combinations for data access 510. In some embodiments, the delay combination can be selected once, such as at the end of a manufacturing process or a qualification process. For such embodiments, the method 500 can include selecting one or more delay paths within the first delay circuit 406 and/or the second delay circuit 408 that provide the most consistent signal separation across the environmental conditions. For example, the method 500 can include computing, for each delay path or a combination of delay paths across the first and second delay circuits, a difference in the signal separations between the different environmental settings. The method 500 can select the delay path/combination having the lowest computed difference across the tested environmental settings.

In other embodiments, the delay combination can be selected dynamically, such as according to real-time conditions that occur after deployment of the apparatus 100. For such embodiments, the method 500 can include determining the path that minimize the signal separations and/or maintain the signal separation relatively consistent across the different conditions. For example, the method 500 can include determining a set of paths that together maintain the signal separations closest to each and at the shortest duration other across the tested environmental settings.

At block 512, the method 500 can include storing the selection within the apparatus 100. In some embodiments, the selected path or a combination of paths can be hardwired or set within the first delay circuit 406 and/or the second delay circuit 408. In other embodiments, identifiers for the selected path or the combination of paths can be stored, such as using fuses. For dynamically determining the path, the links or relationships between the tested levels and the selected paths can be stored, such as a lookup table.

Various forms of the selections can be stored in the selection control circuit 412 of FIG. 4. Examples of the selection control circuit 412 can include fuses, embedded read-only memory, logic settings, or a combination thereof.

The test for the delay behavior and the delay path selection can occur during manufacturing and/or qualification of the apparatus 100. After the apparatus 100 is deployed, such as by selling to an end user or a system integrator, the apparatus 100 can operate according to the test results and selection.

For the illustrated embodiments, the method 500 can include detecting a power on event for the apparatus 100 as shown in block 520. At block 522, the apparatus can determine the access delay as shown in block 522. The apparatus 100 can determine the access delay based on the stored selection. In some embodiments, the apparatus 100 can establish the stored settings as shown in block 524. For example, the apparatus 100 can broadcast the fuse settings that identify the selected paths and locally store (e.g., in latches) the broadcasted data as shown in block 526. In other embodiments, the apparatus 100 can.

At block 530, the apparatus 100 can enable communication over the selected delay path. For example, the selector circuit 410 can use the locally stored information and/or the dynamically identified path to enable or utilize the selected delay path(s), such as by enabling the corresponding set of the delay components 409 of FIG. 4 and/or enabling the corresponding selection gate/component using the selector circuit 410 of FIG. 4.

At block 532, the apparatus 100 can utilize the selected delay path to operate the read circuit 200 of FIG. 2. For example, the apparatus 100 can use the selected path in the first delay circuit 406 and/or the second delay circuit 408 to control the timings of the first control voltage 422 and/or the second control voltage 424. Using the delayed output, the first adjusted control voltage 422b and/or the second adjusted control voltage 424b can be used to provide the respective ones of the first input voltage 302 and/or the second input voltage. In other words, the bank logic 180 can use the delay circuit 185 to time the first adjusted control voltage 422b and/or the second adjusted control voltage 424b. The delayed outputs can be provided to the driver circuit 190, and the driver circuit 190 can cause the first voltage transition 306 of FIG. 3 and/or the second voltage transition 308 of FIG. 3 according to the delayed and timed outputs from the selection control circuit 412.

For the dynamic selections, the apparatus 100 can determine a trigger condition for reevaluating the delay setting. For example, the apparatus 100 can determine the trigger condition according to a predetermined frequency, a change in error rates, a number of performed operations, or a combination thereof. As shown by the feedback loop to block 528, the apparatus 100 can dynamically detect the operating condition in response to determining the trigger condition. Accordingly, the apparatus can adjust/update the delay path selection according to real-time conditions.

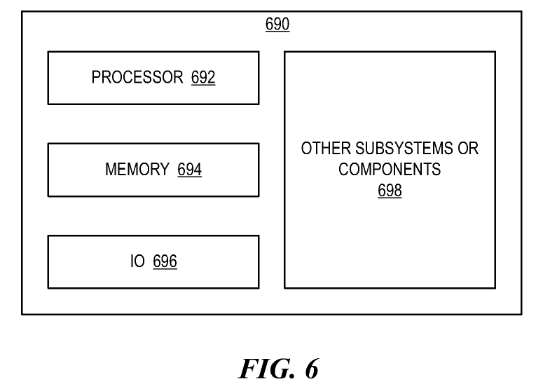

FIG. 6 is a schematic view of a system that includes an apparatus in accordance with embodiments of the present technology. Any one of the foregoing apparatuses (e.g., memory devices) described above with reference to FIGS. 1-5 can be incorporated into any of a myriad of larger and/or more complex systems, a representative example of which is system 600 shown schematically in FIG. 6. The system 600 can include a processor 602, a memory device 604, a power source 606, a driver 608, and/or other subsystems or components 610.

The memory device 604 can include features generally similar to those of the apparatus described above with reference to FIGS. 1-5 and can therefore include various features for performing a direct read request from a host device. The resulting system 600 can perform any of a wide variety of functions, such as memory storage, data processing, and/or other suitable functions. Accordingly, representative systems 600 can include, without limitation, hand-held devices (e.g., mobile phones, tablets, digital readers, and digital audio players), computers, vehicles, appliances and other products. Components of the system 600 may be housed in a single unit or distributed over multiple, interconnected units (e.g., through a communications network). The components of the system 600 can also include remote devices and any of a wide variety of computer readable media.

From the foregoing, it will be appreciated that specific embodiments of the technology have been described herein for purposes of illustration, but that various modifications may be made without deviating from the disclosure. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

In the illustrated embodiments above, the apparatuses have been described in the context of DRAM devices. Apparatuses configured in accordance with other embodiments of the present technology, however, can include other types of suitable storage media in addition to or in lieu of DRAM devices, such as, devices incorporating NAND-based or NOR-based non-volatile storage media (e.g., NAND flash), magnetic storage media, phase-change storage media, ferroelectric storage media, etc.

The term "processing" as used herein includes manipulating signals and data, such as writing or programming, reading, erasing, refreshing, adjusting or changing values, calculating results, executing instructions, assembling, transferring, and/or manipulating data structures. The term data structure includes information arranged as bits, words or code-words, blocks, files, input data, system-generated data, such as calculated or generated data, and program data. Further, the term "dynamic" as used herein describes processes, functions, actions or implementation occurring during operation, usage or deployment of a corresponding device, system or embodiment, and after or while running manufacturer's or third-party firmware. The dynamically occurring processes, functions, actions or implementations can occur after or subsequent to design, manufacture, and initial testing, setup or configuration.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to FIGS. 1-6.

We claim:

1. A memory device comprising:
memory cells configured to store charges representative of data values;
a sense amplifier coupled to the memory cells and configured to amplify the stored charges for reading the data values, wherein the sense amplifier is configured to amplify using a first input voltage and a second input voltage;
a control logic coupled to the sense amplifier and configured to generate a first control voltage and a second control voltage, wherein the first control voltage is for controlling the first input voltage and the second control voltage is for controlling the second input voltage; and
at least one delay circuit coupled to the control logic and the sense amplifier, the at least one delay circuit configured to provide an adjustable delay to at least one of the first control voltage and the second control voltage.

2. The memory device of claim 1, wherein the at least one delay circuit includes two or more delay paths that each provide a different amount of delay for the first control voltage and/or the second control voltage, wherein the adjustable delay corresponds to an output from one of the delay paths that has been preselected.

3. The memory device of claim 2, wherein the selected one of the delay paths is identified using trim settings that are stored using fuses.

4. The memory device of claim 1, wherein the at least one delay circuit is configured to (1) delay the first control voltage for reducing the unintended delay from the transition of the first input voltage to the transition of the second input voltage and (2) without delaying the second control voltage.

5. The memory device of claim 1, wherein the at least one delay circuit includes:
a first delay circuit including a first set of delay paths that are each configured to provide a different amount of delay for the first control voltage; and
a second delay circuit including a second set of delay paths that are each configured to provide a different amount of delay for the second control voltage,
wherein the adjustable delay corresponds to selections of one delay path from each of the first and second sets of delay paths.

6. The memory device of claim 5, wherein the first set of delay paths and the second set of delay paths include matching number of delay paths.

7. The memory device of claim 1, wherein:
the control logic and the at least one delay circuit comprise a bank logic;
the memory device further comprising:
a driver disposed between the at least one delay circuit and the sense amplifier and configured to generate the first input voltage and the second input voltage according to the first control voltage and the second control voltage as delayed by the at least one delay circuit.

8. The memory device of claim 1, wherein:
the second control voltage is within a domain of a system voltage V_{DD} provided from an external source to the memory device; and
the multiple levels of the operating condition corresponds to different levels of the system voltage V_{DD}.

9. The memory device of claim 1, wherein:
the sense amplifier is one of N number of sense amplifiers; and
the at least one delay circuit is one of N number of delay circuit groupings that each have 1-to-1 connection to one of the N number of sense amplifiers.

10. The memory device of claim 1, further comprising:
a multiplexer disposed between the at least one delay circuit and the sense amplifier;
wherein:
the sense amplifier is one of N number of sense amplifiers; and
the at least one delay circuit is one of M number of delay circuit groupings that are each coupled to and shared by a grouping of N/M number of sense amplifiers.

11. The memory device of claim 1, wherein:
the first input voltage corresponds to an ACT voltage supplied to one end of the sense amplifier; and
the second input voltage corresponds to a RNL voltage supplied to an opposing end of the sense amplifier, wherein the ACT voltage is higher than the RNL voltage.

12. The memory device of claim 1, wherein the memory device comprises a Dynamic Random-Access Memory (DRAM).

13. An apparatus comprising:
a charge storage circuit configured to store charges according to two or more charge ranges;
an amplifier coupled to the charge storage circuit and configured to amplify the stored charges for determining a corresponding one of the two or more charge ranges, wherein the amplifier is configured to amplify using a first input voltage and a second input voltage;
a control logic coupled to the amplifier and configured to generate at least a first control signal and a second control signal for operating the amplifier; and
a delay circuit coupled to the control logic and the amplifier, the delay circuit configured to provide a set of selectable delays for the first and/or the second control signals, wherein one delay setting from the set of selectable delays is configured to be selected for controlling a temporal separation between the first input voltage and a second input voltage.

14. The apparatus of claim 13, wherein the set of selectable delays includes a set of selectable delay paths with each path including a unique number of delay elements.

15. The apparatus of claim 13, wherein:
the delay circuit is a first delay circuit configured to control a first delay for the first control signal; and
the apparatus further comprising:
a second delay circuit configured to control a second delay for the second control signal.

16. The apparatus of claim 13, further comprising:
a selector circuit coupled to the delay circuit and configured to persistently store an identifier for the selected one delay setting within the set of selectable delays; and
a selection control circuit coupled to the delay circuit and configured to apply the selected one delay, based on the identifier, to the first and/or the second control signals.

17. The apparatus of claim 13, wherein:
the charge storage circuit is configured to store the charges representative of one of multiple bit values;
the amplifier is a sense amplifier configured to amplify the stored charges for determining the represented one of the bit values, wherein the first input voltage is an ACT input voltage and the second input voltage is a RNL input voltage for the sense amplifier; and
the delay circuit is configured to provide the set of selectable delays for controlling a delay between the ACT input voltage and a RNL input voltage.

18. A method of operating a memory device, the method comprising:
determining a predetermined delay setting for operating a sense amplifier in the memory device;
selecting a delay path according to the predetermined delay setting; and
communicating a control signal over the delay path, wherein the control signal is configured to control an input voltage to the sense amplifier.

19. The method of claim 18, wherein:
determining the predetermined delay setting includes reading an identifier from a set of fuses;
selecting the delay path includes activating an output gate corresponding to the identifier, the output gate corresponding to a selected path from a set of delay paths that each provide different delays; and
the input voltage includes an ACT input voltage separate from a RNL input voltage provided to the sense amplifier used to determine a bit value represented by charges stored at a memory cells; and
communicating the control signal over the delay path includes controlling a delay between the ACT input voltage and the RNL input voltage.

20. The method of claim 19, further comprising:
testing delay patterns across the set of delay paths under multiple system voltage (V_{DD}) levels that are provided to the memory device from an external source;
identifying the selected path having a lowest difference in delays between the ACT and RNL input voltages across the V_{DD} levels amongst the set of delay paths; and
storing the identifier corresponding to the selected path in persistent memory within the memory device.
